(19) United States
(12) Patent Application Publication
(10) Pub. No.: US 2024/0221792 A1
(43) Pub. Date: Jul. 4, 2024

(54) REFLOW PROTECTION FOR A MODULE SEMICONDUCTOR DEVICE

(71) Applicant: Micron Technology, Inc., Boise, ID (US)

(72) Inventor: Minjian WU, Shanghai (CN)

(21) Appl. No.: 18/523,151

(22) Filed: Nov. 29, 2023

(30) Foreign Application Priority Data
Dec. 29, 2022 (CN) 202211710160.6

(51) Int. Cl. G11C 5/00; G11C 11/4078

(52) U.S. Cl. CPC G11C 5/005; G11C 11/4078

(57) ABSTRACT

In some implementations, a memory device may configure a reflow critical data region in a non-volatile memory that is associated with at least one reflow protection measure for data stored in the reflow critical data region. The memory device may write a set of data to the reflow critical data region. The memory device may determine that a reflow process associated with the memory device has been completed. The memory device may reconfigure the reflow critical data region to remove the at least one reflow protection measure based on determining that the reflow process has been completed.

### CROSS-REFERENCE TO RELATED APPLICATION

This Patent Application claims priority to Chinese Patent Application No. 202211710160.6, filed on Dec. 29, 2022, entitled “REFLOW PROTECTION FOR A MODULE SEMICONDUCTOR DEVICE,” and assigned to the assignee hereof. The disclosure of the prior Application is considered part of and is incorporated by reference into this Patent Application.

### TECHNICAL FIELD

The present disclosure generally relates to memory devices, memory device operations, and, for example, to reflow protection for a module semiconductor device.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g.,

DRAM) may lose stored data over time unless the volatile memory is refreshed by a power source.

### BRIEF DESCRIPTION OF THE DRAWINGS

FIG. 1 is a diagram illustrating an example system capable of providing reflow protection for a module semiconductor device.

FIG. 2 is a diagram of example components included in a memory device.

FIG. 3 is a diagram illustrating an example of single-level cell, multi-level cell (MLC), triple-level cell, and quad-level cell non-volatile memory.

FIG. 4 is a diagram illustrating an example of read errors that may occur in an MLC non-volatile memory device.

FIGS. 5A-5B are example systems associated with module semiconductor devices.

FIG. 6 is a diagram of an example process associated with manufacturing a module semiconductor device having reflow protection.

FIG. 7 is a diagram of an example associated with reflow protection for a module semiconductor device.

FIG. 8 is a diagram of an example associated with reflow protection for the module semiconductor device described above in connection with FIG. 5A.

FIG. 9 is a flowchart of an example method associated with reflow protection for a module semiconductor device.

### DETAILED DESCRIPTION

In some applications, memory devices may be provided as part of a module semiconductor device (sometimes referred to herein as simply a “module”). A module semiconductor device may include a module board (e.g., a printed circuit board (PCB)) with multiple components electrically coupled to (e.g., soldered to) the module board. For example, a module semiconductor device may include a system on chip (SoC) component as well as one or more memory components, such as a dynamic random access memory (DRAM) component, a managed NAND (mNAND) component, a multichip package (MCP) component, or a similar memory component. An original equipment manufacturer (OEM) may be provided with a module semiconductor device, and the OEM may integrate the module semiconductor device into a larger system by electrically coupling (e.g., soldering) the module board to a carrier board (e.g., a PCB) associated with the system. In some examples, use of a module semiconductor device may result in lower PCB costs, fewer PCB layers required for carrier boards, better control of signal integrity for traces between the SoC component and the one or more memory components on the module board, and similar benefits.

In some examples, manufacturing a system that includes a module semiconductor device may be performed in two main processes, with a first process being performed by a module manufacturer and the second process being performed at the OEM or a similar system manufacturer. More particularly, the module manufacturer may mount, to the module board, one or more components, such as the SoC component and the one or more memory components (e.g., a DRAM component, an mNAND component, an MCP, or a similar memory component). Prior to mounting the components to the module board, the module manufacturer may refrain from loading any data to the components in order to avoid potential corruption of data during the manufacturing process. More particularly, the one or more components may be mounted to the module board using a soldering reflow process, during which the components may be subjected to high temperatures that could potentially change threshold voltages associated with data stored in memory cells or otherwise corrupt data stored in memory cells. Accordingly, in some examples, the one more components may be soldered to the module board prior to writing any data to the one or more memory components in order to avoid corruption of any data stored thereon.

Following mounting of the components to the module board, the one or more components may undergo an in-system programming step by the module manufacturer in order to download a system boot image (e.g., firmware and/or similar instructions) to the one or more memory components. The module manufacturer may then test the module to ensure that the system boot image has been downloaded correctly and/or to ensure the module semiconductor device is operating correctly. During the module testing step, additional data (sometimes referred to herein as key data and/or critical data) may be generated, such as calibration data associated with the module semiconductor device. The additional data (e.g., the key data and/or critical data) may be stored in one or more memory components of the module semiconductor device for later use by the OEM and/or a system in which the module semiconductor device is integrated, such as for purposes of calibrating the module semiconductor device in the larger system.

At the OEM, the module semiconductor device may be mounted to the carrier board, such as via a reflow soldering process or a similar process. Due to the heat generated during the mounting process, some data on the module semiconductor device may become corrupt during mounting of the module semiconductor device to the carrier board. Accordingly, following mounting of the module semiconductor device to the carrier board, the module semiconductor device may undergo an in-system programming step in order to update certain data, such as by updating the system boot image in order to repair any data that may have become corrupt during the mounting process. However, certain data may not be capable of being updated, such as the key or critical data (e.g., calibration data) generated during the module test phase at the module manufacturer, because this data may be module-specific and thus may not be repairable by a generic system boot image. Accordingly, this data may be stored within the module semiconductor device in a way to ensure that the key data does not become corrupt during mounting of the module semiconductor device to the carrier board. For example, single level cell (SLC) memory may be more robust and/or resistant to corruption during the mounting process than higher-bit memory (e.g., multi-level cell (MLC) memory, triple-level cell (TLC) memory, quad-level cell (QLC) memory, or the like), because the threshold voltages associated with SLCs may have greater margins. Accordingly, key or critical data (e.g., calibration data) may be stored in SLCs in order to reduce the likelihood of corruption of the data during the mounting process or other manufacturing step. For example, one more memory components of a module semiconductor device may include an SLC partition to store key data, and a TLC partition to store other data (e.g., a system boot image). However, providing an SLC partition for the key data reduces a density associated with the one or more memory components, thus reducing the overall capacity of the one or more memory components. As a result, module semiconductor devices may be unable to meet OEM requirements and/or may be otherwise unsuitable for certain high-density applications.

Some implementations described herein enable increased density and/or capacity of memory components associated with module semiconductor devices while maintaining reflow protection, thereby protecting certain key data from corruption during a module mounting step or similar process. In some implementations, one or more memory devices of a module semiconductor device may be configured with a reflow critical region associated with at least one reflow protection measure. For example, the reflow critical region may be associated with an SLC mode, such that data saved in the reflow critical region may be more robust to high temperatures and/or less likely to be corrupted during a soldering reflow process when mounting the module semiconductor device to a carrier board during an OEM mounting process. Following the reflow process, the reflow critical data region may be reconfigured to remove the at least one reflow protection measure, such as by associating the reflow critical region with a TLC mode and/or by moving key data (e.g., calibration data or similar data originally stored in the reflow critical region) to TLC storage. In this regard, a density and/or capacity of the module semiconductor device may be increased following the reflow process, thereby enabling the use of a module semiconductor device for high-density applications and other applications having high storage requirements while still maintaining reflow protection during the module mounting steps. These and other features will become more apparent with reference to the figures.

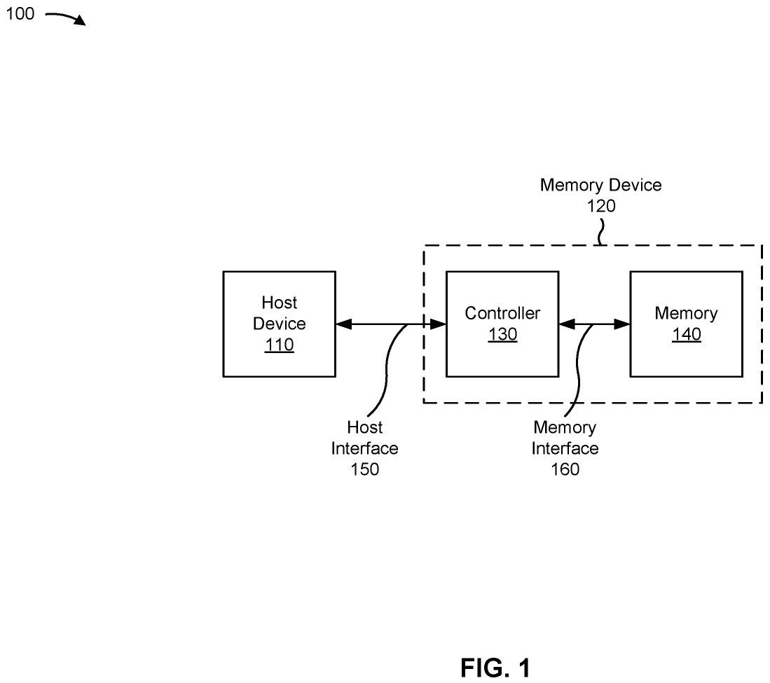

FIG. 1 is a diagram illustrating an example system 100 capable of providing reflow protection for a module semiconductor device. The system 100 may include one or more devices, apparatuses, and/or components for performing operations described herein. For example, the system 100 may include a host device 110 and a memory device 120. The memory device 120 may include a controller 130 and memory 140. The host device 110 may communicate with the memory device 120 (e.g., the controller 130 of the memory device 120) via a host interface 150. The controller 130 and the memory 140 may communicate via a memory interface 160.

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host device 110 may include one or more processors configured to execute instructions and store data in the memory 140. For example, the host device 110 may include a central processing unit (CPU), a graphics processing unit (GPU), a field-programmable gate array (FPGA), an application-specific integrated circuit (ASIC), and/or another type of processing component.

The memory device 120 may be any electronic device or apparatus configured to store data in memory. In some implementations, the memory device 120 may be an electronic device configured to store data persistently in non-volatile memory. For example, the memory device 120 may be a hard drive, a solid-state drive (SSD), a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device. In this case, the memory 140 may include non-volatile memory configured to maintain stored data after the memory device 120 is powered off. For example, the memory 140 may include NAND memory or NOR memory. In some implementations, the memory 140 may include volatile memory that requires power to maintain stored data and that loses stored data after the memory device 120 is powered off, such as one or more latches and/or random-access memory (RAM), such as dynamic RAM (DRAM) and/or static RAM (SRAM). For example, the volatile memory may cache data read from or to be written to non-volatile memory, and/or may cache instructions to be executed by the controller 130.

The controller 130 may be any device configured to communicate with the host device (e.g., via the host interface 150) and the memory 140 (e.g., via the memory interface 160). Additionally, or alternatively, the controller 130 may be configured to control operations of the memory device 120 and/or the memory 140. For example, the controller 130 may include a memory controller, a system controller, an ASIC, an FPGA, a processor, a microcontroller, and/or one or more processing components. In some implementations, the controller 130 may be a high-level controller, which may communicate directly with the host device 110 and may instruct one or more low-level controllers regarding memory operations to be performed in connection with the memory 140. In some implementations, the controller 130 may be a low-level controller, which may receive instructions regarding memory operations from a high-level controller that interfaces directly with the host device 110. As an example, a high-level controller may be an SSD controller, and a low-level controller may be a non-volatile memory controller (e.g., a NAND controller) or a volatile memory controller (e.g., a DRAM controller). In some implementations, a set of operations described herein as being performed by the controller 130 may be performed by a single controller (e.g., the entire set of operations may be performed by a single high-level controller or a single low-level controller). Alternatively, a set of operations described herein as being performed by the controller 130 may be performed by more than one controller (e.g., a first subset of the operations may be performed by a high-level controller and a second subset of the operations may be performed by a low-level controller).

The host interface 150 enables communication between the host device 110 and the memory device 120. The host interface 150 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, and/or an embedded multimedia card (eMMC) interface.

The memory interface 160 enables communication between the memory device 120 and the memory 140. The memory interface 160 may include a non-volatile memory interface (e.g., for communicating with non-volatile memory), such as a NAND interface or a NOR interface. Additionally, or alternatively, the memory interface 160 may include a volatile memory interface (e.g., for communicating with volatile memory), such as a double data rate (DDR) interface.

In some implementations, the memory device 120 and/or the controller 130 may be configured to configure a reflow critical data region in a non-volatile memory that is associated with at least one reflow protection measure for data stored in the reflow critical data region; write a set of data to the reflow critical data region; determine that a reflow process associated with the memory device has been completed; and reconfigure the reflow critical data region to remove the at least one reflow protection measure based on determining that the reflow process has been completed.

As indicated above, FIG. 1 is provided as an example. Other examples may differ from what is described with regard to FIG. 1.

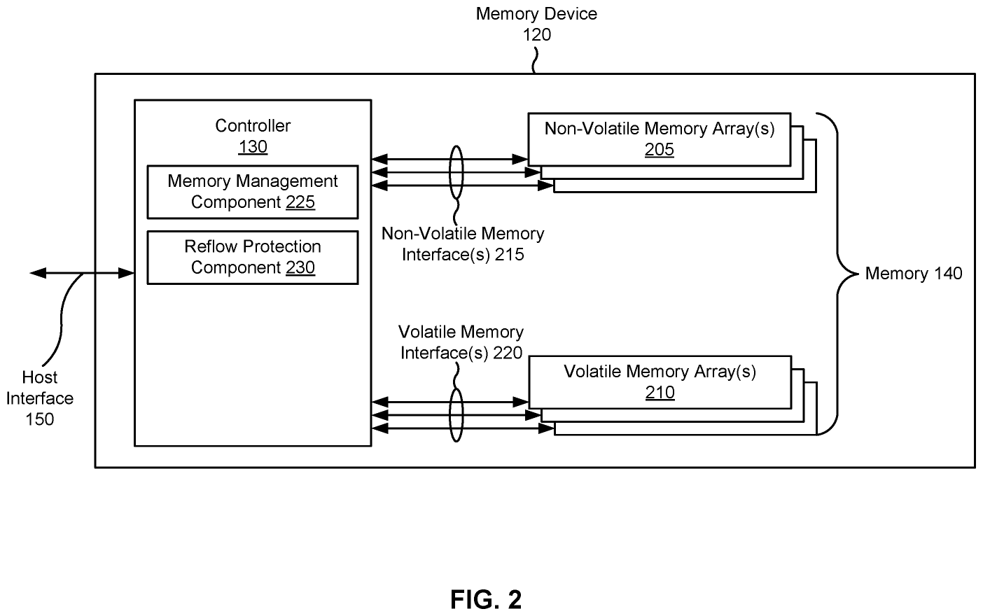

FIG. 2 is a diagram of example components included in a memory device 120. As described above in connection with FIG. 1, the memory device 120 may include a controller 130 and memory 140. As shown in FIG. 2, the memory 140 may include one or more non-volatile memory arrays 205, such as one or more NAND memory arrays and/or one or more NOR memory arrays. Additionally, or alternatively, the memory 140 may include one or more volatile memory arrays 210, such as one or more SRAM arrays and/or one or more DRAM arrays. The controller 130 may transmit signals to and receive signals from a non-volatile memory array 205 using a non-volatile memory interface 215. The controller 130 may transmit signals to and receive signals from a volatile memory array 210 using a volatile memory interface 220.

The controller 130 may control operations of the memory 140, such as by executing one or more instructions. For example, the memory device 120 may store one or more instructions in the memory 140 as firmware, and the controller 130 may execute those one or more instructions. Additionally, or alternatively, the controller 130 may receive one or more instructions from the host device 110 via the host interface 150, and may execute those one or more instructions. In some implementations, a non-transitory computer-readable medium (e.g., volatile memory and/or non-volatile memory) may store a set of instructions (e.g., one or more instructions or code) for execution by the controller 130. The controller 130 may execute the set of instructions to perform one or more operations or methods described herein. In some implementations, execution of the set of instructions, by the controller 130, causes the controller 130 and/or the memory device 120 to perform one or more operations or methods described herein. In some implementations, hardwired circuitry is used instead of or in combination with the one or more instructions to perform one or more operations or methods described herein. Additionally, or alternatively, the controller 130 and/or one or more components of the memory device 120 may be configured to perform one or more operations or methods described herein. An instruction is sometimes called a “command.”

For example, the controller 130 may transmit signals to and/or receive signals from the memory 140 based on the one or more instructions, such as to transfer data to (e.g., write or program), to transfer data from (e.g., read), and/or to erase all or a portion of the memory 140 (e.g., one or more memory cells, pages, sub-blocks, blocks, or planes of the memory 140). Additionally, or alternatively, the controller 130 may be configured to control access to the memory 140 and/or to provide a translation layer between the host device 110 and the memory 140 (e.g., for mapping logical addresses to physical addresses of a memory array). In some implementations, the controller 130 may translate a host interface command (e.g., a command received from the host device 110) into a memory interface command (e.g., a command for performing an operation on a memory array).

As shown in FIG. 2, the controller 130 may include a memory management component 225 and/or a reflow protection component 230. In some implementations, one or more of these components are implemented as one or more instructions (e.g., firmware) executed by the controller 130. Alternatively, one or more of these components may be implemented as dedicated integrated circuits distinct from the controller 130.

The memory management component 225 may be configured to manage performance of the memory device 120. For example, the memory management component 225 may perform wear leveling, bad block management, block retirement, read disturb management, and/or other memory management operations. In some implementations, the memory device 120 may store (e.g., in memory 140) one or more memory management tables. A memory management table may store information that may be used by or updated by the memory management component 225, such as information regarding memory block age, memory block erase count, and/or error information associated with a memory partition (e.g., a memory cell, a row of memory, a block of memory, or the like).

The reflow protection component 230 may be configured to configure certain portions of the memory 140 to provide reflow protection for key data associated with the memory device 120. In some implementations, the reflow protection component 230 may be configured to configure a reflow critical data region in a non-volatile memory (e.g., non-volatile memory array 205), write data to the reflow critical data region, and/or reconfigure the reflow critical data region to remove at least one reflow protection measure after determining that a reflow process associated with the memory device 120 has been completed. In some implementations, the reflow protection component 230 is configured to alternatively configure the reflow critical data region to operate in an SLC mode and a higher-level mode, such as an MLC mode, a TLC mode, or a QLC mode.

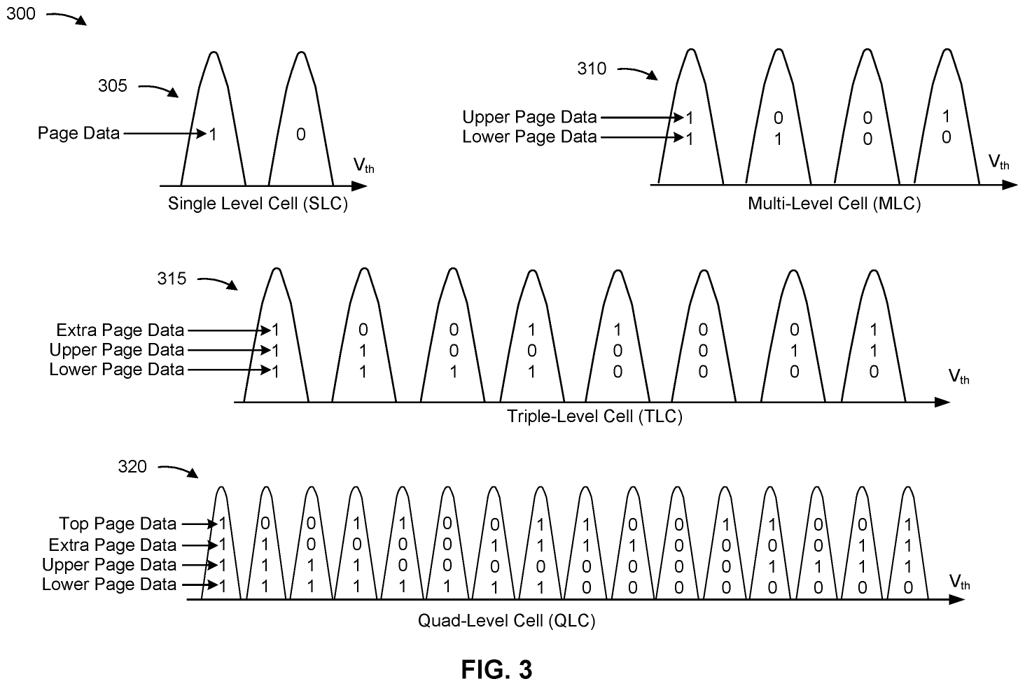

One or more devices or components shown in FIG. 2 may be configured to perform operations described herein, such as one or more operations and/or methods described in connection with FIGS. 3-9. For example, the controller 130, the memory management component 225, and/or the reflow protection component 230 may be configured to perform one or more operations and/or methods for the memory device 120.

The number and arrangement of components shown in FIG. 2 are provided as an example. In practice, there may be additional components, fewer components, different components, or differently arranged components than those shown in FIG. 2. Furthermore, two or more components shown in FIG. 2 may be implemented within a single component, or a single component shown in FIG. 2 may be implemented as multiple, distributed components. Additionally, or alternatively, a set of components (e.g., one or more components) shown in FIG. 2 may perform one or more operations described as being performed by another set of components shown in FIG. 2.

FIG. 3 is a diagram illustrating an example 300 of SLC, MLC, TLC, and QLC non-volatile memory. One or more of these memory types may be used by a memory device described herein.

In some cases, a non-volatile memory device, such as a NAND device, may store bits of data by charging or not charging memory cells, which may be capable of retaining a charge (e.g., electrons) even when no voltage is applied to the cell. For example, a non-volatile, solid-state memory device (e.g., a flash memory device) may include a floating gate transistor configured to store electrical charge. The floating gate transistor may be isolated above and below by insulating oxide layers. The floating gate transistor may be charged by applying a high voltage to a control gate proximate to a first (or top) insulating layer (sometimes called a gate oxide), which causes electrons from a substrate proximate to a second (or bottom) insulating layer (sometimes called a tunnel oxide) to tunnel through the second insulating layer and to the floating gate, which is sometimes referred to as tunneling or Fowler-Nordheim tunneling. Conversely, the floating gate transistor may be erased by applying a high voltage to the substrate, which causes electrons from the floating gate transistor to tunnel through the second insulating layer and to the substrate. A lack of charge in the floating gate transistor, a presence of a charge in the floating gate transistor, and/or a level of the charge in the floating gate transistor indicates a data state stored by the memory cell or floating gate transistor. In some other examples, a memory device may include a charge trap transistor configured to store electrical charge. In a charge trap type memory device, data is programmed or erased by providing or removing charges in or from a charge trap layer (e.g., a silicon-nitride (SiN) storage layer) through tunneling or injecting of electrons into the charge trap layer in a memory cell. The charge trap layer may be a dielectric material that can trap charges, thereby permitting the storage layer to be shared and continuous among the memory cells. Because in some implementations a word line is formed in the memory device by replacing one or more SiN films originally stacked in the memory device during a manufacturing process, charge trap memory devices are sometimes referred to as replacement gate (RG) memory devices.

More particularly, a non-volatile memory cell, such as a NAND cell, may be categorized as an SLC, an MLC, a TLC, or a QLC, among other examples. As shown by reference number 305, an SLC stores a single binary bit per memory cell, and thus may store either binary 1 or binary 0. In an SLC, the stored bit is sometimes referred to as the page data of the memory cell. When writing to an SLC, the cell may be charged to a threshold voltage (Vₜₕ) falling within the distribution of the curve labeled with page data “1” when the memory cell is to store binary 1 (or else may include no charge when the memory cell is to store binary 1), and may be charged to a threshold voltage falling within the distribution of the curve labeled with page data “0” when the memory cell is to store binary 0.

Unlike an SLC, which only stores a single bit, an MLC, a TLC, and a QLC may store multiple bits per memory cell. More particularly, as shown by reference number 310, an MLC stores two binary bits per memory cell, and thus is capable of storing binary 11, binary 01, binary 00, or binary 10 according to a level of a charged stored in the MLC. In an MLC, a first stored bit is sometimes referred to as the cell's upper page data, and the second stored bit is sometimes referred to as the cell's lower page data. When writing to an MLC, the cell may be charged to a threshold voltage falling within the distribution of the curve labeled with page data “11” when the memory cell is to store binary 11, the cell may be charged to a threshold voltage falling within the distribution of the curve labeled with page data “01” when the memory cell is to store binary a 01, the cell may be charged to a threshold voltage falling within the distribution of the curve labeled with page data “00” when the memory cell is to store binary 00, and the cell may be charged to a threshold voltage falling within the distribution of the curve labeled with page data “10” when the memory cell is to store binary 10. In some implementations, an MLC stores binary 11 when the MLC's charge is approximately 25% full, the MLC stores binary 01 when the MLC's charge is approximately 50% full, the MLC stores binary 00 when the MLC's charge is approximately 75%, and the MLC stores binary 10 when the MLC's charge is approximately 100% full.

In a similar manner, and as shown by reference number 315, a TLC stores three binary bits per memory cell, and thus a TLC is capable of storing binary 111, binary 011, binary 001, binary 101, binary 100, binary 000, binary 010, or binary 110. For a TLC, the first, second, and third stored bits are sometimes referred to as the cell's “extra page data,” the cell's “upper page data,” and the cell's “lower page data,” respectively. Moreover, as shown by reference number 320, a QLC stores four binary bits per memory cell, and thus is capable of storing binary 1111, binary 0111, binary 0011, binary 1011, binary 1001, binary 0001, binary 0101, binary 1101, binary 1100, binary 0100, binary 0000, binary 1000, binary 1010, binary 0010, binary 0110, or binary 1110. For a QLC, the first, second, third, and fourth bits are sometimes referred to as the cell's “top page data,” the cell's “extra page data,” the cell's “upper page data,” and the cell's “lower page data,” respectively. More broadly, for an n-bit memory cell, the threshold voltage of the cell may be programmed to 2ⁿ separate states, with each state corresponding to a non-overlapping threshold distribution, as shown for the various memory cells in FIG. 3.

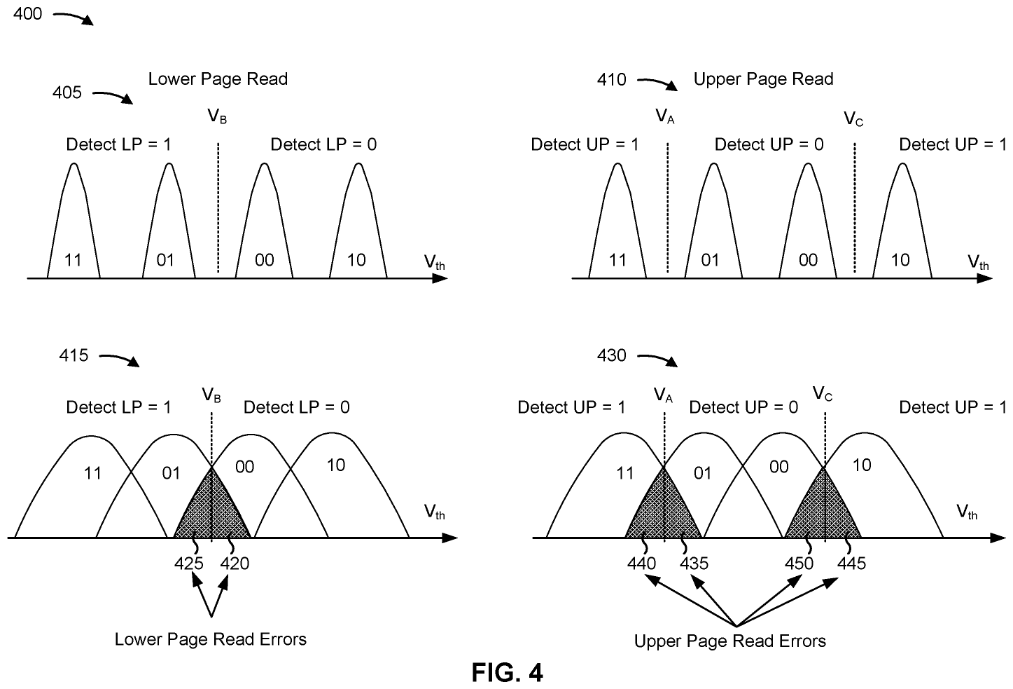

To read the data stored in a memory cell, such as an SLC, an MLC, a TLC, a QLC, or another type of memory cell, a memory device (or a component thereof) may sense a voltage associated with the stored charge on the memory cell (e.g., may sense a Vₜₕ associated with the cell) and determine a corresponding binary number associated with that voltage. Details regarding reading a memory cell, including detecting and correcting read errors, are described in more detail below in connection with FIG. 4.

As indicated above, FIG. 3 is provided as an example. Other examples may differ from what is described with regard to FIG. 3.

FIG. 4 is a diagram illustrating an example 400 of read errors that may occur in an MLC non-volatile memory device. Although the read errors described in connection with FIG. 4 are described in the context of an MLC, the described concepts also apply to other types of memory cells, such as SLCs, TLCs, QLCs, and other types of memory cells.

To read the data of a memory cell, such as the MLC shown in FIG. 4, the memory device (or a component thereof) may apply a read reference voltage to the cell in an effort to induce current in the memory cell, and the memory device (or a component thereof) may determine a corresponding bit string associated with a voltage that induced (or else did not induce) current. Put another way, the memory device may apply various read reference voltages to sense the threshold voltage (Vₜₕ ) associated with the data stored in the cell.

More particularly, for an MLC, the memory device may perform a lower page (also shown as LP) read and an upper page (also shown as UP) read. As shown by reference number 405, for a lower page read, the memory device may apply to a read reference voltage, shown as V_{B}. V_{B} may represent a voltage between threshold voltage distributions associated with the first two states (e.g., threshold voltage distributions associated with binary 11 and 01) and threshold voltage distributions associated with the second two states (e.g., threshold voltage distributions associated with binary 00 and 10). If current flows when V_{B} is applied to the memory cell, then the threshold voltage may be considered to be less than V_{B}, thus corresponding to one of binary 11 or binary 01 (meaning that the lower page data represents a “1”). If current does not flow when V_{B} is applied to the memory cell, then the threshold voltage may be considered to be more than V_{B}, thus corresponding to one of binary 00 or binary 10 (meaning that the lower page data represents a “0”).

As shown by reference number 410, an upper page read may be performed in a similar manner. More particularly, when the detected lower page data is a “1”, a read reference voltage of V_{A} may be applied to the memory cell to thereafter determine the upper page data. V_{A} may represent a voltage between a threshold voltage distribution associated with the first state (e.g., a threshold voltage distribution associated with binary 11) and a threshold voltage distribution associated with the second state (e.g., a threshold voltage distribution associated with binary 01). If current flows when V_{A} is applied to the memory cell, then the threshold voltage may be considered to be less than V_{A}, thus corresponding to binary 11 (meaning that the upper page data represents a “1”). If current does not flow when V_{A} is applied to the memory cell, then the threshold voltage may be considered to be more than V_{A} but less than V_{B} (as determined during the lower page read), thus corresponding to binary 01 (meaning that the upper page data represents a “0”).

Similarly, when the detected lower page data is a “0,” a read reference voltage of V_{C} may be applied to the memory cell to thereafter determine the upper page data. V_{C} may represent a voltage between a threshold voltage distribution associated with the third state (e.g., a threshold voltage distribution associated with binary 00) and a threshold voltage distribution associated with the fourth state (e.g., a threshold voltage distribution associated with binary 10). If current flows when V_{C} is applied to the memory cell, then the threshold voltage may be considered to be less than V_{C} but more than V_{B} (as determined during the lower page read), thus corresponding to binary 00 (meaning that the upper page data represents a “0”). If current does not flow when V_{C} is applied to the memory cell, then the threshold voltage may be considered to be more than V_{C}, thus corresponding to binary 10 (meaning that the upper page data represents a “1”).

In some cases, the threshold voltage distributions shown in FIG. 4 may be broadened due to noise or the like, which may lead to read errors at the memory device. Noise in the memory cell may be caused by various sources, such as program-erase (P/E) cycling stress, charge leakage over time, read disturbances (e.g., disturbances caused by the application of a high voltage to a memory cell of a page not being read to deselect the cell while other cells on the page are being read), programming errors, cell-to-cell interference (such as unintentional electrical disturbance and/or interference of a memory cell when neighboring cells are read, written, or erased), heat application during a reflow process or similar manufacturing process, or the like. As shown in FIG. 4, broadened voltage threshold distributions may lead to read errors, such as lower page read errors and/or upper page read errors.

First, as shown by reference number 415, a lower page read error may be caused by the broadening of voltage distributions that are near V_{B} and/or that overlap with V_{B}. In the example shown in FIG. 4, the threshold voltage distributions associated with binary 01 and binary 00 have broadened to overlap with the read reference voltage V_{B}. This may result in a lower page read error because a cell programmed with binary 01 may act in a similar manner to a cell programmed with binary 00 (e.g., in response to an applied voltage). More particularly, if V_{B} is applied to a memory cell that stores binary 01 but that is associated with a threshold voltage in the area labeled with reference number 420, no current would flow, erroneously indicating that the lower page data represents a “0” rather than a “1”. On the other hand, if V_{B} is applied to a memory cell that stores binary 00 but that is associated with a threshold voltage in the area labeled with reference number 425, current would flow, erroneously indicating that the lower page data represents a “1” rather than a “0”.

Similarly, as shown by reference number 430, when performing an upper page read, an upper page read error may be caused by the broadening of voltage distributions that are near V_{A} and/or V_{C} and/or that overlap with V_{A} and/or V_{C}. For example, memory cells storing binary 11 and associated with a threshold voltage in the area labeled by 435 may be erroneously read as storing upper page data of “0”, memory cells storing binary 01 and associated with a threshold voltage in the area labeled by 440 may be erroneously read as storming upper page data of “1”, memory cells storing binary 00 and associated with a threshold voltage in the area labeled by 445 may be erroneously read as storing upper page data of “1”, and memory cells storing binary 10 and associated with a threshold voltage in the area labeled by 450 may be erroneously read as storing upper page data of “0”.

In some cases, a memory device may attempt to adjust one or more read reference voltages in response to one or more of the read errors described above (e.g., in response to a cell storing one logical value or binary number being misread as storing a different logical value or binary number). In some instances, this may be referred to as a read retry or a read recovery process. In a read recovery process, one or more read reference voltages (such as V_{A}, V_{B}, or V_{C} described in connection with the MLC) may be dynamically adjusted to track changes in threshold voltage distributions. More particularly, once a read process fails on a particular page of a memory, the memory device (and, more particularly, the controller and/or a read recovery component thereof) may attempt to recover the page using various read recovery steps, which use shifts in voltages from base read reference voltages. Put another way, the memory device may retry the read of a cell with an adjusted read reference voltage such that read errors are decreased or eliminated.

Returning to the example shown in FIG. 4, if a lower page error resulted in a cell storing binary 00 being read as binary 01, the read reference voltage (V_{B}) may be decreased (e.g., shifted to the left in the diagram shown by reference number 415) in an effort to eliminate the lower page read error. Conversely, if a lower page error resulted in a cell storing binary 01 being read as binary 00, the read reference voltage (V_{B}) may be increased (e.g., shifted to the right in the diagram shown by reference number 415). Similarly, the read reference voltages V_{A} and V_{C} may be shifted left or right (e.g., decreased or increased) in an effort to reduce or eliminate upper page read errors.

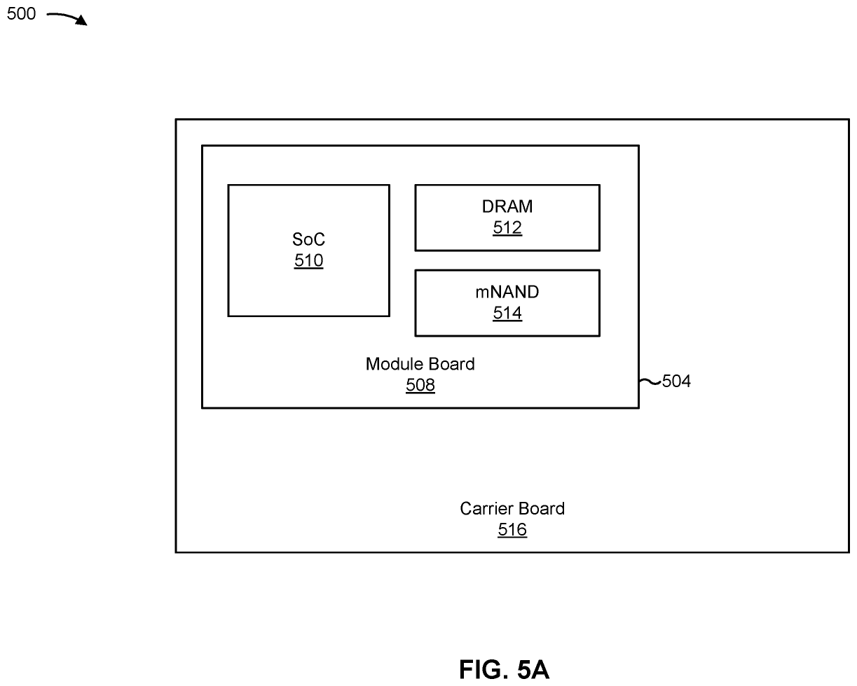

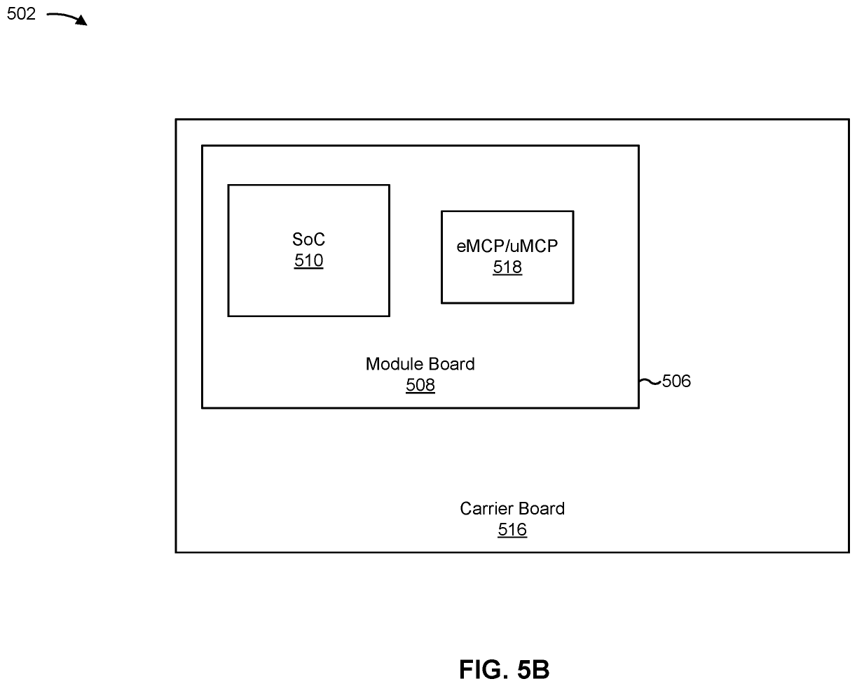

Memory cells storing fewer bits of information per cell may be more robust and/or less prone to read errors than memory cells storing more bits of information per cell. For example, SLCs may be more robust than MLCs, which in turn may be more robust than TLCs, which in turn may be more robust than QLCs. This is because the fewer information bits that a memory cell is associated with, the fewer threshold voltages are associated with the cell, providing a greater margin for the threshold voltages to broaden and/or shift without adversely affecting read operations. Accordingly, in some implementations, certain key data may be stored in SLC memory in order to avoid corruption of the data during a reflow process or similar high-temperature process that may cause a broadening and/or shifting of voltage levels within memory cells, thus leading to read errors in multi-bit cells such as MLCs, TLCs, QLCs, or higher bit cells. Storing key data using SLC memory is described in more detail below in connection with FIGS. 5A-9.

As indicated above, FIG. 4 is provided as an example. Other examples may differ from what is described with regard to FIG. 4.

FIGS. 5A-5B are example systems 500, 502 associated with module semiconductor devices 504, 506. The module semiconductor devices 504, 506 described in connection with FIGS. 5A-5B may be associated with and/or correspond to the memory device 120 and/or one or more components of the memory device 120, such as the controller 130 and/or one or more components of the controller 130. Additionally, or alternatively, the module semiconductor devices 504, 506 may be referred to simply as “memory devices” herein.

As shown in FIG. 5A, the module semiconductor device 504 may include multiple components electrically coupled to a module board 508, such as a PCB or a similar board. In some implementations, the module semiconductor device 504 may include an SoC component 510 and one or more memory components communicatively connected to the SoC component 510. In the example system 500 shown in FIG. 5A, the module semiconductor device 504 may include a volatile memory component, such as a DRAM component 512, and a non-volatile memory component, such an mNAND component 514. The various components may be bonded to the module board 508 via solder bonds or similar bonds. In some implementations, the various components may be soldered to the module board 508 via a solder reflow process.

In some implementations, using a solder reflow process to mount the various components to the module board 508 may generate high temperatures at the module board 508, which may corrupt data stored on the one or more components (e.g., data stored in the mNAND component 514). Accordingly, in some implementations, a module manufacturer may refrain from writing any data to the memory components (e.g., the mNAND component 514) until after the reflow process is complete. For example, the module manufacturer may download or otherwise write a system boot image to the mNAND component 514 after bonding the mNAND component 514 to the module board 508 via the reflow process.

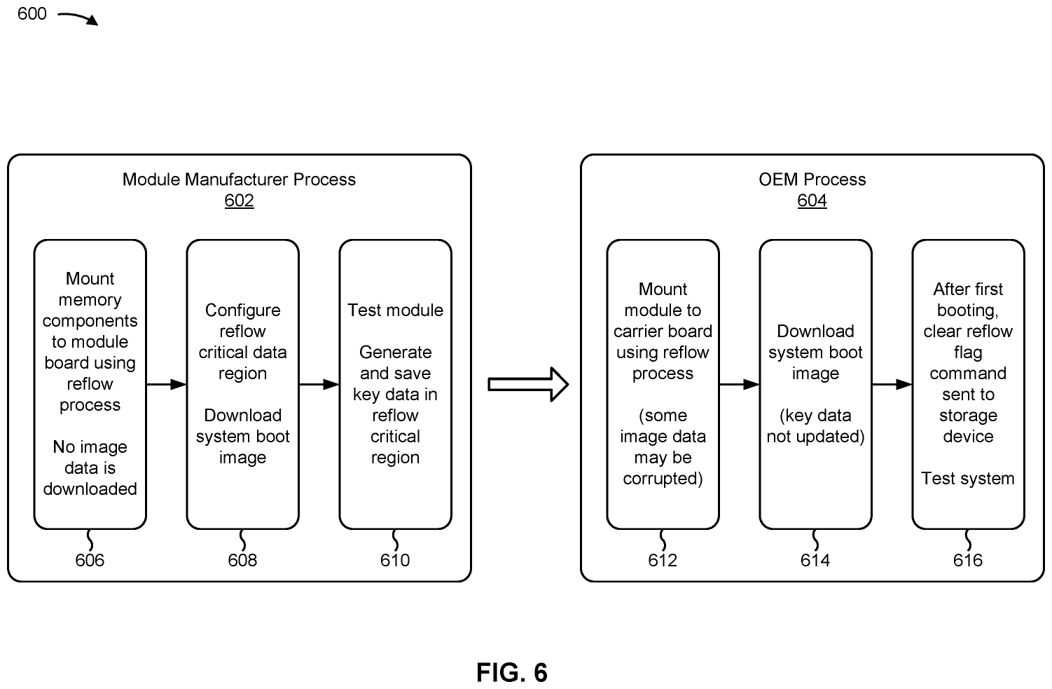

In some implementations, an OEM or other manufacturer may later mount the module semiconductor device 504 to a carrier board 516 (e.g., a PCB) associated with a larger system. More particularly, the OEM or other manufacture may solder the module board 508 of the module semiconductor device 504 to the carrier board 516 using a reflow process or the like. In some implementations, bonding the module semiconductor device 504 to the carrier board 516 may generate large amounts of heat, which may corrupt any data stored on the various components of the module semiconductor device 504 (e.g., data stored in the mNAND component 514). Accordingly, in some implementations, any data that cannot be re-downloaded and/or re-written to the mNAND component 514 following mounting of the module board 508 to the carrier board 516 (sometimes referred to as key data and/or critical data) may be stored in an area of the mNAND component 514 that includes reflow protection in order to mitigate the risk of corruption of the data during the module semiconductor device 504 mounting process. For example, in some implementations, key data may be stored in SLC memory, which may be less susceptible than TLC memory to data corruption caused by a reflow mounting process. Details of storing key data in an area of the mNAND component 514 that includes reflow protection is described in more detail below in connection with FIGS. 6-9.

Although the example system 500 described in connection with FIG. 5A includes a DRAM component 512 and an mNAND component 514 as example memory components that may be mounted to the module board 508, in some other implementations, other types of memory components may be employed in a module semiconductor device. For example, as shown by the example system 502 in FIG. 5B, the module semiconductor device 506 may include the SoC component 510 and an MCP component 518, such as an embedded MCP (eMCP), a UFS-based MCP (uMCP), or a similar type of MCP. In such examples, certain key data may be stored in a memory location of the MCP component 518 that includes reflow protection, which is described in more detail below in connection with FIGS. 6-9.

As indicated above, FIGS. 5A-5B are provided as examples. Other examples may differ from what is described with regard to FIGS. 5A-5B.

FIG. 6 is a diagram of an example process 600 associated with manufacturing a module semiconductor device having reflow protection. The operations described in connection with FIG. 6 may be performed by the memory device 120 and/or one or more components of the memory device 120, such as the controller 130 and/or one or more components of the controller 130; the module semiconductor device 504, 506 and/or one or more components of the module semiconductor device 504, 506, such as the SoC component 510, the mNAND component 514, and/or the MCP component 518; and/or by various semiconductor manufacturing equipment (e.g., a soldering tool, a reflow oven, or similar equipment). The example process 600 may include two main stages: a first stage performed by a module semiconductor device manufacturer, sometimes referred to as a “module manufacturer process,” as indicated by reference number 602 in FIG. 6; and a second stage performed by an OEM or similar manufacturer, sometimes referred to as an “OEM process,” as indicated by reference number 604 in FIG. 6.

As shown by reference number 606, the module manufacturer may mount certain components to a module board (e.g., module board 508), such as by using a solder reflow process or a similar process. For example, the module manufacturer may mount the SoC component 510, the DRAM component 512, the mNAND component 514, and/or the MCP component 518 to the module board 508 using a solder reflow process (sometimes referred to simply as a “reflow process” herein). As described in detail above in connection with FIGS. 5A-5B, because this process may generate high temperatures that may otherwise corrupt data stored in one or more of the components being mounted to the module board, the module manufacturer may refrain from downloading any data to the one or more components prior to the reflow process.

As shown by reference number 608, following mounting of the various components to the module board, a reflow critical data region may be configured in a non-volatile memory (e.g., the mNAND component 514, the MCP component 518) of the module semiconductor device. In some implementations, the reflow critical data region may be a region of the non-volatile memory that is associated with at least one reflow protection measure for data stored in the reflow critical data region. For example, the at least one reflow protection measure may include storing the set of data using an SLC mode. As described above, SLC memory may be less prone to corruption during a reflow process, and thus configuring the reflow critical data region to operate in an SLC mode (e.g., to store one bit of data per memory cell) may adequately protect data stored therein from corruption during subsequent reflow processes performed by an OEM or similar manufacturer. Additionally, or alternatively, the at least one reflow protection measure may include storing the set of data using altered threshold voltages, sometimes referred to herein as “special trims.” “Altered threshold voltages” and/or “special trims” may refer to threshold voltages that differ from default write threshold voltages, such as the threshold voltage distributions described above in connection with FIG. 3. For example, the set of data may be stored using trims that compensate for shifting and/or broadening threshold voltages that may result during future reflow processes so that the data may thereafter be read within minimal data loss.

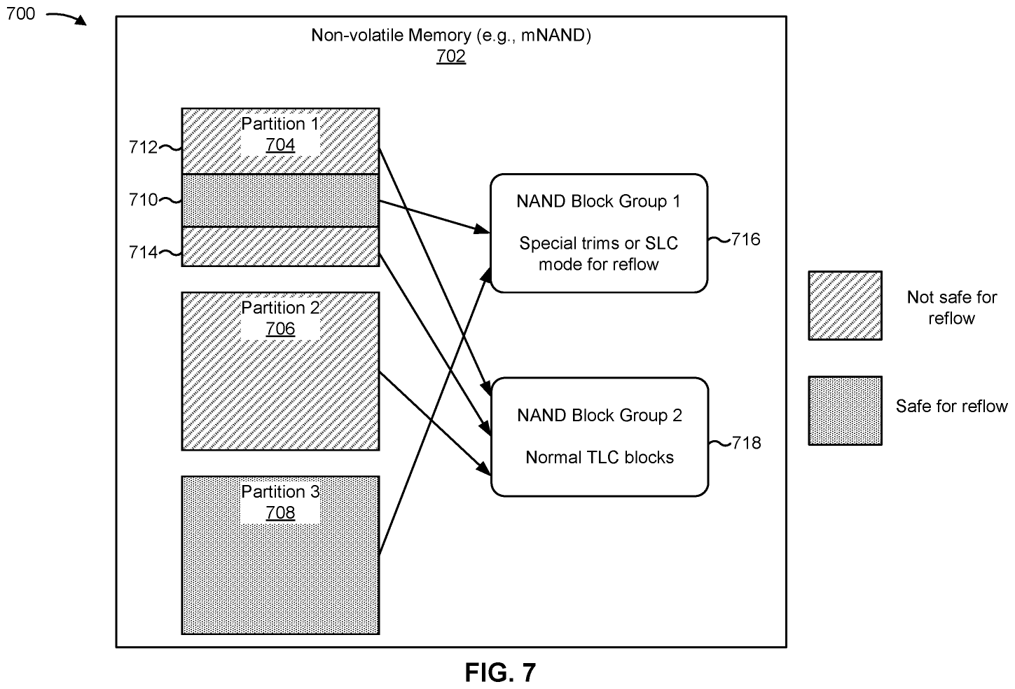

In that regard, following configuration of the reflow critical data region, the non-volatile memory may be associated with both the reflow critical data region as well as a non-reflow critical data region (e.g., a portion of the non-volatile memory that is not configured with at least one reflow protection measure). Accordingly, some data (e.g., key data, calibration data, and/or similar data) may be written to the reflow critical data region (e.g., a region configured to operate in an SLC mode and/or associated with special trims), which may be protected from corruption during subsequent reflow processes, and other data (e.g., a system boot image or similar data that is capable of being re-downloaded or otherwise repaired following subsequent reflow processes) may be written to the non-reflow critical data region (e.g., a region configured to operate in a TLC mode), which may not be protected from corruption during subsequent reflow processes. Details regarding examples of the reflow critical data region and the non-reflow critical region are described in more detail below in connection with FIG. 7.

As shown by reference number 610, following download of the system boot image (e.g., firmware associated with the SoC component and/or operations of the module semiconductor device), the module manufacturer may test the module semiconductor device. During the testing phase, certain key data may be generated, which may be specific to the particular module semiconductor device being tested. For example, the key data may be associated with calibration data applicable to the particular module semiconductor device being tested. In that regard, because this key data is specific and/or customized to the particular module semiconductor device being tested and thus cannot be re-generated simply by re-downloading a generic system boot image or similar firmware, the key data may be written to the reflow critical data region. Accordingly, because the reflow critical data region is associated with at least one reflow protection measure, the key data may be protected during subsequent reflow processes performed downstream (e.g., a reflow process performed by an OEM or similar manufacturer).

More particularly, as shown by reference number 612, an OEM or a similar manufacturer may receive the module semiconductor device, which may include various components (e.g., the SoC component 510, the DRAM component 512, the mNAND component 514, the MCP component 518, and/or a similar component) mounted to the module board (e.g., module board 508). As described above in connection with reference numbers 606 and 608, the module semiconductor device (and, more particularly, a non-volatile memory of the module semiconductor device) may be pre-loaded with certain data. For example, the module semiconductor device may include a system boot image or similar firmware stored in a non-reflow critical data region (e.g., a region of the non-volatile memory operating in a TLC mode), and/or key data (e.g., calibration data or similar module-specific data) stored in a reflow critical data region (e.g., a region of the non-volatile memory associated with at least one reflow protection measure, such as a region operating in an SLC mode and/or associated with special trims).

The OEM may mount the module semiconductor device to a carrier board (e.g., carrier board 516), such as by using a solder reflow process. More particularly, the OEM may mount the module board associated with the module semiconductor device to the carrier board to thereby establish an electrical connection between the module semiconductor device and the carrier board, in a similar manner as described in detail above in connection with FIGS. 5A-5B. This reflow process may generate high temperatures at the module board, causing some data that is pre-loaded to the module semiconductor device (e.g., to a non-volatile memory associated with the module semiconductor device) to become corrupt. For example, some data stored using multi-bit cells (e.g., memory cells operating in a TLC mode) may be prone to corruption during the reflow process. However, certain data that is associated with a reflow protection measure may be less likely to become corrupt during the reflow process. For example, the key data stored in the reflow critical data region, which may be a region associated with memory operating in an SLC mode and/or using special trims (as described above), may be protected from corruption during the reflow process.

As shown by reference number 614, in some implementations, the OEM may repair corrupted data, such as by re-downloading a system boot image and/or firmware associated with the module semiconductor device. As described above, because the system boot image or similar data may be generic (e.g., may not be specific to the particular module semiconductor device and/or may not include customized data associated with the particular module semiconductor device), this data may be more readily repaired and/or re-downloaded by the OEM. However, certain module-specific data (e.g., key data, such as calibration data or similar data) may not be updated at this step, as described above.

As shown by reference number 616, in some implementations, following mounting the module semiconductor device to the carrier board (e.g., following the reflow process performed at the OEM or similar manufacture), the reflow critical data region may be reconfigured in order to remove the at least one reflow protection measure, because the module semiconductor device may no longer be subjected to high temperatures and/or other risks of manufacturing-induced data corruption. For example, in implementations in which the key data is stored in a region of the non-volatile memory associated with SLC memory and/or is associated with special trims, the data may be moved to TLC cells and/or the reflow critical region may be reconfigured to operate as TLC cells. In this regard, a density and/or capacity of the one or more memory components may be increased following the reflow process, because the SLC memory used to store the key data may be reconfigured as TLC memory, increasing the storage capacity of that portion of the memory three-fold.

In some implementations, reconfiguring the reflow critical data region to remove the at least one reflow protection measure may be based on the module semiconductor device determining that a reflow process associated with the module semiconductor device (e.g., the reflow process described in connection with reference number 612) has been completed. For example, in some implementations, following the reflow process, and/or upon booting the module semiconductor device for the first time in the OEM system, one or more components of the module semiconductor device may be configured to transmit, to the non-volatile memory of the module semiconductor device, a clear reflow flag command indicating that the reflow critical data region may be reconfigured to remove the at least one reflow protection measure (e.g., indicating that the SLC memory used to store key data may be reconfigured as TLC memory, or a similar operation). In some implementations, the clear reflow flag command may be included in a system boot image written to the non-volatile memory after the reflow process has been completed. More particularly, the system boot image downloaded as part of the module manufacturer process, as described above in connection with reference number 608, may not include the clear reflow flag command, such that when the module semiconductor device is booted and tested by the module manufacturer (as described above in connection with reference number 610), the module semiconductor device does not receive a command to remove the reflow protection measure. However, the system boot image downloaded as part of the OEM process, as described above in connection with reference number 614, may include the clear reflow flag command, such that when the module semiconductor device is booted and tested by the OEM manufacturer (as described above in connection with reference number 616, which has occurred after the reflow process used to mount the module semiconductor device to the carrier board), the module semiconductor device receives the command to remove the reflow protection measure, and thus reconfigures the reflow critical data region accordingly (e.g., reconfigures the reflow critical data region from operating in an SLC mode to operating in a TLC mode).

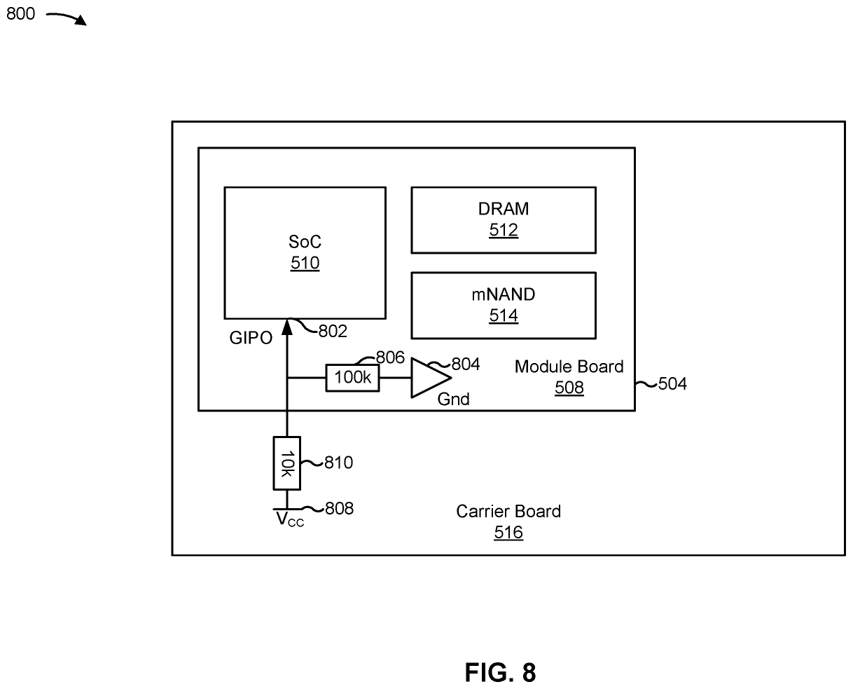

Additionally, or alternatively, the module semiconductor device may use the same system boot image at the module manufacturer process (e.g., for the operations described above in connection with reference number 608) and the OEM process (e.g., for the operations described above in connection with reference number 614); however, there may be a different software flow when booting the module semiconductor device prior to the reflow process and after the reflow process. In such examples, the module semiconductor device may be configured to determine that the reflow process associated with the memory device has been completed (and thus that the at least one reflow proception measure may be removed) based on a voltage level associated with a general purpose input/output (GPIO) of the module semiconductor device. For example, hardware associated with the module semiconductor device may result in a first voltage (or lack of voltage) being applied to a GPIO of the module semiconductor device (e.g., a GPIO of the SoC component 510) when the module semiconductor device is booted during the module maker process, and may result in a second voltage (or lack of voltage) being applied to the GPIO of the module semiconductor device when the module semiconductor device is booted during the OEM process. In such implementations, in response to the first voltage being present at the GPIO, the module semiconductor device may refrain from sending the clear reflow flag command, and, in response to the second voltage being present at the GPIO, the module semiconductor device may transmit the clear reflow flag command. Hardware features that may be employed to implement the first voltage and the second voltage at the GPIO are described in more detail below in connection with FIG. 8.

As indicated above, FIG. 6 is provided as an example. Other examples may differ from what is described with regard to FIG. 6.

FIG. 7 is a diagram of an example 700 associated with reflow protection for a module semiconductor device. The operations described in connection with FIG. 7 may be performed by the memory device 120 and/or one or more components of the memory device 120, such as the controller 130 and/or one or more components of the controller 130, and/or by the module semiconductor device 504, 506 and/or one or more components of the module semiconductor device 504, 506, such as the SoC component 510, the mNAND component 514, and/or the MCP component 518.

In some implementations, a module semiconductor device (e.g., the module semiconductor device 504, 506) may be associated with multiple memory block groups, with at least a first memory block group being associated with the reflow critical data region, and with at least a second memory block group being associated with the non-reflow critical data region. More particularly, as shown in the example 700, the module semiconductor device (more particularly, one or more memory components of the module semiconductor device) may be associated with a non-volatile memory 702, such as an mNAND memory, an MCP memory, or a similar memory. The non-volatile memory 702 may be associated with multiple partitions, such as a first partition 704 (shown as “Partition 1”), a second partition 706 (shown as “Partition 2”), and a third partition 708 (shown as “Partition 3”). Each partition may be associated with multiple blocks of memory, which may be configurable to operate in an SLC mode, an MLC mode, a TLC mode, a QLC mode, or a similar mode. For example, in some implementations the blocks of each partition may be configurable to operate in an SLC mode, such as for purposes of storing key data (e.g., calibration data) with reflow protection, or else in a TLC mode, such as for purposes of storing normal data (e.g., non-key data) and/or all data following a reflow process (following mounting of the module semiconductor device to a carrier board).

As shown in FIG. 7, full partitions and/or partial partitions may be configured as safe for reflow (e.g., may be configured for use to store key data during a reflow process). More particularly, in this example, the third partition 708 and a first portion 710 of the first partition 704 may be configured as safe for reflow. Put another way, the third partition 708 and the first portion 710 of the first partition 704 may be configured as the reflow critical data region. The remaining partitions and/or portions of partitions may thus be considered as not-safe-for-reflow (e.g., may be used to store data for which it is not critical that the data avoid corruption during a reflow process). More particularly, the second partition 706, a second portion 712 of the first partition 704, and a third portion 714 of the first partition 704 may be left as not-safe-for-reflow. Put another way, the second partition 706, the second portion 712 of the first partition 704, and the third portion 714 of the first partition 704 may be configured as the non-reflow critical data region.

In that regard, the portions of the partitions associated with the safe-for-reflow region and/or the reflow critical data region may be associated with a first block group 716 (shown as a “NAND block group 1” in FIG. 7) that is associated with reflow protection, and the portions of the partitions associated with the not-safe-for-reflow region and/or the non-reflow critical data region may be associated with a second block group 718 (shown as a “NAND block group 2” in FIG. 7) that is not associated with reflow protection. For example, the first block group 716 may be associated with special trims and/or may be operating in an SLC mode during the reflow process, and the second block group 718 may be operating in a TLC mode (e.g., may be operating as normal TLC blocks) during the reflow process. Accordingly, the module semiconductor device may be configured to write a first set of data to the first block group 716, such as key or critical data that is specific to the particular module semiconductor device and/or data for which it is otherwise important that the data survive a reflow process, and the module semiconductor device may be configured to write a second set of data to the second block group 718, such as generic data (e.g., firmware) that is common to multiple module semiconductor devices and/or data that can be easily repaired and/or re-downloaded, if necessary, following a reflow process.

As indicated above, FIG. 7 is provided as an example. Other examples may differ from what is described with regard to FIG. 7.

FIG. 8 is a diagram of an example 800 associated with reflow protection for the module semiconductor device 504 described above in connection with FIG. 5A. Although for ease of discussion the hardware features described in connection with FIG. 8 are described in connection with the module semiconductor device 504 described above in connection with FIG. 5A (e.g., a module semiconductor device including a DRAM component 512 and an mNAND component 514), implementations are not so limited. In some other implementations, similar operations and/or features may be associated with other module semiconductor devices, such as the module semiconductor device 506 described above in connection with FIG. 5B (e.g., a module semiconductor device including an MCP component 518).

As described above in connection with reference number 616, in some implementations, the non-volatile memory of a module semiconductor device may receive a clear reflow flag command following the reflow process, in response to which the module semiconductor device may remove the at least one reflow protection measure associated with the reflow critical data region (e.g., may reconfigure the reflow critical data region from operating in an SLC mode to operating in a TLC mode). In some implementations, the clear reflow flag command may be triggered according to a voltage present at a GPIO associated with the module semiconductor device (e.g., associated with the SoC component 510 of the module semiconductor device 504).

More particularly, in some implementations, a GPIO 802 of the SoC component 510 may be electrically coupled to a ground potential 804 (shown as “Gnd” in FIG. 8) of the module board 508 via a first resistor 806. In some implementations, the first resistor 806 may be associated with a relatively high resistance, such as 100 kiloohms (kΩ) (shown in FIG. 8 as “100 k”). When the module board 508 has not yet been mounted to the carrier board 516, the GPIO 802 may be associated with the ground potential via the first resistor 806. In such implementations, upon booting up the module semiconductor device 504 (e.g., to test the module semiconductor device 504, as described above in connection with reference number 610), the GPIO value may be identified as “0,” and thus the module semiconductor may follow a software flow that does not include the clear reflow flag command. Put another way, the module semiconductor device 504 may determine that a reflow process that will be used to mount the module semiconductor device 504 to the carrier board 514 has not yet been performed based on the GPIO being associated with a “0” value, and thus the module semiconductor device 504 may maintain the reflow protection for the reflow critical data region (e.g., the first block group 716).

After the module board 508 is mounted to the carrier board 516, the module semiconductor device 504 (e.g., the SoC component 510 of the module semiconductor device 504) may be electrically coupled to a voltage source 808 (e.g., a supply voltage and/or a common collector voltage, shown as V_{CC}) on the carrier board 516 via a second resistor 810. In some implementations, the second resistor 810 may be associated with a relatively low resistance, such as 10 kΩ (shown in FIG. 8 as “10 k”). In such implementations, upon booting up the module semiconductor device 504 (e.g., to test the module semiconductor device 504, as described above in connection with reference number 616), the voltage now present at the GPIO, as a result of the additional 10 kΩ pulled to V_{CC}, may be identified as “1,” and thus the module semiconductor device 504 may follow a software flow that does include the clear reflow flag command. Put another way, the module semiconductor device 504 may determine that the reflow process used to mount the module semiconductor device 504 to the carrier board 514 has been performed based on the GPIO being associated with a “1” value, and thus the module semiconductor device 504 may remove the reflow protection for the reflow critical data region (e.g., the first block group 716). In such implementations, the key data or other data stored in the reflow critical data region may be moved to normal TLC blocks in the background. In this regard, density and/or capacity of the module semiconductor device 504 may be increased following the reflow process, thereby enabling the use of a module semiconductor device for high-density applications and other applications having high storage requirements while still maintaining reflow protection during the module mounting steps.

As indicated above, FIG. 8 is provided as an example. Other examples may differ from what is described with regard to FIG. 8.

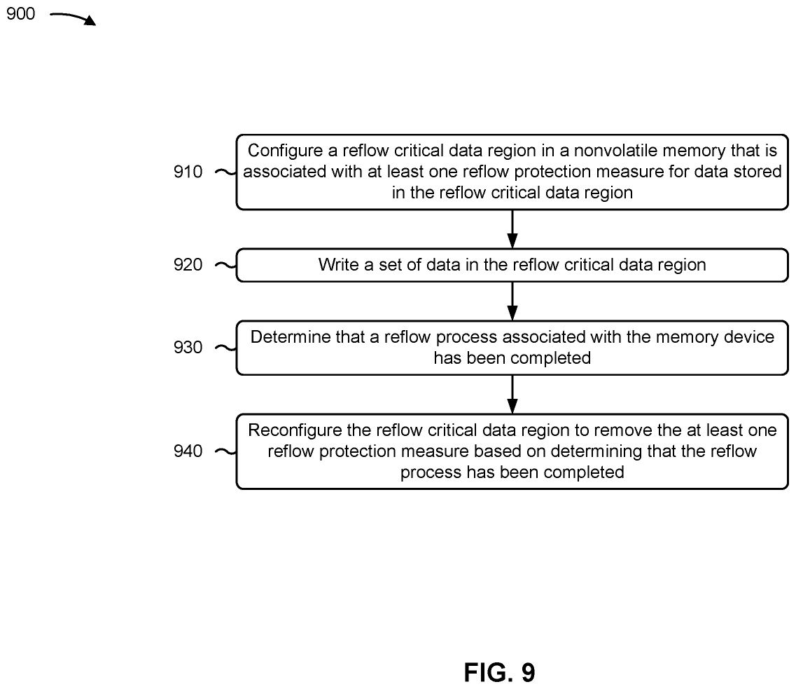

FIG. 9 is a flowchart of an example method 900 associated with reflow protection for a module semiconductor device. In some implementations, a memory device (e.g., the memory device 120) and/or a module semiconductor device (e.g., the module semiconductor device 504, 506) may perform or may be configured to perform the method 900. In some implementations, another device or a group of devices separate from or including the memory device (e.g., the system 100) may perform or may be configured to perform the method 900. Additionally, or alternatively, one or more components of the memory device (e.g., the controller 130, the memory management component 225, and/or the reflow protection component 230) may perform or may be configured to perform the method 900. Thus, means for performing the method 900 may include the memory device and/or one or more components of the memory device. Additionally, or alternatively, a non-transitory computer-readable medium may store one or more instructions that, when executed by the memory device (e.g., the controller 130 of the memory device 120), cause the memory device to perform the method 900.

As shown in FIG. 9, the method 900 may include configuring a reflow critical data region in a non-volatile memory that is associated with at least one reflow protection measure for data stored in the reflow critical data region (block 910). As further shown in FIG. 9, the method 900 may include writing a set of data to the reflow critical data region (block 920). As further shown in FIG. 9, the method 900 may include determining that a reflow process associated with the memory device has been completed (block 930). As further shown in FIG. 9, the method 900 may include reconfiguring the reflow critical data region to remove the at least one reflow protection measure based on determining that the reflow process has been completed (block 940).

The method 900 may include additional aspects, such as any single aspect or any combination of aspects described below and/or described in connection with one or more other methods or operations described elsewhere herein.

In a first aspect, the non-volatile memory is associated with multiple block groups, a first block group, of the multiple block groups, is associated with the reflow critical data region, and a second block group, of the multiple block groups, is associated with a non-reflow critical data region.

In a second aspect, alone or in combination with the first aspect, the method 900 may further include writing another set of data to the non-reflow critical data region.

In a third aspect, alone or in combination with one or more of the first and second aspects, the at least one reflow protection measure includes storing the set of data using a single level cell mode prior to the reflow process associated with the memory device being completed.

In a fourth aspect, alone or in combination with one or more of the first through third aspects, removing the at least one reflow protection measure includes storing the set of data using a triple level cell mode.

In a fifth aspect, alone or in combination with one or more of the first through fourth aspects, the at least one reflow protection measure includes storing the set of data using altered threshold voltages prior to the reflow process associated with the memory device being completed.

In a sixth aspect, alone or in combination with one or more of the first through fifth aspects, the method 900 may further include transmitting, to the non-volatile memory, a clear reflow flag command, wherein removing the at least one reflow protection measure is further based on the non-volatile memory receiving the clear reflow flag command.

In a seventh aspect, alone or in combination with one or more of the first through sixth aspects, the method 900 may further include determining that the reflow process associated with the memory device has been completed based on a clear reflow flag command included in a system boot image written to the non-volatile memory after the reflow process has been completed.

In an eighth aspect, alone or in combination with one or more of the first through seventh aspects, the method 900 may further include writing another system boot image to the non-volatile memory prior to the reflow process, wherein the other system boot image does not include the clear reflow flag command.

In a ninth aspect, alone or in combination with one or more of the first through eighth aspects, the method 900 may further include determining that the reflow process associated with the memory device has been completed based on a voltage level associated with a general purpose input/output of the memory device.

Although FIG. 9 shows example blocks of a method 900, in some implementations, the method 900 may include additional blocks, fewer blocks, different blocks, or differently arranged blocks than those depicted in FIG. 9. Additionally, or alternatively, two or more of the blocks of the method 900 may be performed in parallel. The method 900 is an example of one method that may be performed by one or more devices described herein. These one or more devices may perform or may be configured to perform one or more other methods based on operations described herein.

In some implementations, a memory device includes one or more components configured to: configure a reflow critical data region in a non-volatile memory that is associated with at least one reflow protection measure for data stored in the reflow critical data region; write a set of data to the reflow critical data region; determine that a reflow process associated with the memory device has been completed; and reconfigure the reflow critical data region to remove the at least one reflow protection measure based on determining that the reflow process has been completed.

In some implementations, a module semiconductor device includes a module board; an SoC component coupled to the module board; and one or more memory components coupled to the module board and communicatively connected to the SoC component, at least one of the SoC component or the one or more memory components configured to: configure a reflow critical data region in a non-volatile memory associated with the one or more memory components that is associated with at least one reflow protection measure for data stored in the reflow critical data region; write a set of data to the reflow critical data region; determine that a reflow process associated with mounting the module board to a carrier board has been completed; and reconfigure the reflow critical data region to remove the at least one reflow protection measure based on determining that the reflow process has been completed.

In some implementations, a method includes configuring, by one or more memory components associated with a module semiconductor device, a reflow critical data region in a non-volatile memory that is associated with at least one reflow protection measure for data stored in the reflow critical data region; writing, by the one or more memory components, a set of data to the reflow critical data region;

determining, by the one or more memory components, that a reflow process associated with mounting the module semiconductor device to a carrier board has been completed; and reconfiguring, by the one or more memory components, the reflow critical data region to remove the at least one reflow protection measure based on determining that the reflow process has been completed.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, the term “approximately” means “within reasonable tolerances of manufacturing and measurement.” As used herein, “satisfying a threshold” may depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
one or more components configured to:
configure a reflow critical data region in a non-volatile memory that is associated with at least one reflow protection measure for data stored in the reflow critical data region;
write a set of data to the reflow critical data region;
determine that a reflow process associated with the memory device has been completed; and
reconfigure the reflow critical data region to remove the at least one reflow protection measure based on determining that the reflow process has been completed.

2. The memory device of claim 1, wherein the non-volatile memory is associated with multiple block groups, wherein a first block group, of the multiple block groups, is associated with the reflow critical data region, and wherein a second block group, of the multiple block groups, is associated with a non-reflow critical data region.

3. The memory device of claim 2, wherein the one or more components are further configured to write another set of data to the non-reflow critical data region.

4. The memory device of claim 1, wherein the at least one reflow protection measure includes storing the set of data using a single level cell mode prior to the reflow process associated with the memory device being completed.

5. The memory device of claim 4, wherein removing the at least one reflow protection measure includes storing the set of data using a triple level cell mode.

6. The memory device of claim 1, wherein the at least one reflow protection measure includes storing the set of data using altered threshold voltages prior to the reflow process associated with the memory device being completed.

7. The memory device of claim 1, wherein the one or more components are further configured to transmit, to the non-volatile memory, a clear reflow flag command, and wherein removing the at least one reflow protection measure is further based on the non-volatile memory receiving the clear reflow flag command.

8. The memory device of claim 1, wherein the one or more components are further configured to determine that the reflow process associated with the memory device has been completed based on a clear reflow flag command included in a system boot image written to the non-volatile memory after the reflow process has been completed.

9. The memory device of claim 8, wherein the one or more components are further configured to write another system boot image to the non-volatile memory prior to the reflow process, and wherein the other system boot image does not include the clear reflow flag command.

10. The memory device of claim 1, wherein the one or more components are further configured to determine that the reflow process associated with the memory device has been completed based on a voltage level associated with a general purpose input/output of the memory device.

11. A module semiconductor device, comprising:
a module board;
a system on chip (SoC) component coupled to the module board; and
one or more memory components coupled to the module board and communicatively connected to the SoC component, at least one of the SoC component or the one or more memory components configured to:
configure a reflow critical data region in a non-volatile memory associated with the one or more memory components that is associated with at least one reflow protection measure for data stored in the reflow critical data region;
write a set of data to the reflow critical data region;
determine that a reflow process associated with mounting the module board to a carrier board has been completed; and
reconfigure the reflow critical data region to remove the at least one reflow protection measure based on determining that the reflow process has been completed.

12. The module semiconductor device of claim 11, wherein the at least one reflow protection measure includes at least one of:
storing the set of data using a single level cell mode prior to the reflow process being completed, or
storing the set of data using altered threshold voltages prior to the reflow process being completed.

13. The module semiconductor device of claim 11, wherein removing the at least one reflow protection measure is further based on the one or more memory components receiving a clear reflow flag command.

14. The module semiconductor device of claim 11, wherein the at least one of the SoC component or the one or more memory components are further configured to determine that the reflow process has been completed based on a signal received from a voltage source associated with the carrier board.

15. A method, comprising:
configuring, by one or more memory components associated with a module semiconductor device, a reflow critical data region in a non-volatile memory that is associated with at least one reflow protection measure for data stored in the reflow critical data region;
writing, by the one or more memory components, a set of data to the reflow critical data region;
determining, by the one or more memory components, that a reflow process associated with mounting the module semiconductor device to a carrier board has been completed; and
reconfiguring, by the one or more memory components, the reflow critical data region to remove the at least one reflow protection measure based on determining that the reflow process has been completed.

16. The method of claim 15, further comprising writing, by the one or more memory components, another set of data to a non-reflow critical data region.

17. The method of claim 15, further comprising:
storing the set of data using a single level cell mode prior to the reflow process being completed; and
storing the set of data using a triple level cell mode after the reflow process has been completed.

18. The method of claim 15, further comprising storing the set of data using altered threshold voltages prior to the reflow process being completed.

19. The method of claim 15, further comprising receiving, by the one or more memory components, a clear reflow flag command, wherein removing the at least one reflow protection measure is further based on the one or more memory components receiving the clear reflow flag command.

20. The method of claim 15, further comprising determining that the reflow process has been completed based on a voltage level associated with a general purpose input/output associated with the module semiconductor device.
